(19) United States
(12) Patent Application Publication
(10) Pub. No.: US 2025/0126698 A1
(43) Pub. Date: Apr. 17, 2025

(54) EUV COLLECTOR FOR AN EUV PROJECTION EXPOSURE APPARATUS

(71) Applicant: Carl Zeiss SMT GmbH, Oberkochen (DE)

(72) Inventors: Silvi HAENDEL, Veldhoven (NL); Michael PURVIS, Veldhoven (NL); Alexander SCHAFGANS, Veldhoven (NL); Yezheng TAO, Veldhoven (NL); Daniel BROWN, Veldhoven (NL); Evan DAVIS, Veldhoven (NL); Haining WANG, Veldhoven (NL); Markus KARL, Kehlheim (DE)

(21) Appl. No.: 18/999,071

(22) Filed: Dec. 23, 2024

Related U.S. Application Data
(63) Continuation of application No. PCT/EP2023/065786, filed on Jun. 13, 2023.
(60) Provisional application No. 63/367,149, filed on Jun. 28, 2022.

(30) Foreign Application Priority Data
Jul. 19, 2022 (DE) 10 2022 207 374.6

(51) Int. Cl. H05G 2/00; G03F 7/00

(52) U.S. Cl. CPC H05G 2/009; G03F 7/70033; G03F 7/7015; G03F 7/702; G03F 7/70233

(57) ABSTRACT

An EUV collector for an EUV projection exposure apparatus transfers usable EUV light emerging from a source volume into a collection volume separated from the source volume. The source volume has a first source extension along a connection axis between a center of the source volume and a center of the collection volume. The source volume has a second, cross section source extension along a cross section axis perpendicular to the connection axis. The EUV collector images the source volume into the collection volume. The imaging has a first imaging scale along the connection axis and a second imaging scale along the cross section axis. The first imaging scale differs from the second imaging scale by at least 10%.

### CROSS-REFERENCE TO RELATED APPLICATIONS

The present application is a continuation of, and claims benefit under 35 USC 120 to, international application No. PCT/EP2023/065786, filed Jun. 13, 2023, which claims benefit under 35 USC 119 of German Application No. 10 2022 207 374.6, filed Jul. 19, 2022. PCT/EP2023/065786 also claims benefit under 35 USC 120 to, U.S. Provisional Application No. 63/367,149, filed Jun. 28, 2022. The entire disclosure of each of these applications is incorporated by reference herein.

### FIELD

The disclosure relates to an EUV collector for an EUV projection exposure apparatus.

### BACKGROUND

EUV collectors for an EUV exposure apparatus are known from DE 10 2019 200 698 A1 and from WO 2009/036957 A1. Further EUV collectors are known from DE 10 2013 204 441 A1 and from DE 10 2013 218 128 A1.

### SUMMARY

The disclosure seeks to provide an EUV collector leading to a higher throughput of usable EUV light to an optical system in a subsequent EUV light path of the EUV projection exposure apparatus.

In an aspect, the disclosure provides an EUV collector for an EUV projection exposure apparatus to transfer usable EUV light emerging from a source volume into a collection volume which is separated from the source volume. The source volume has a first source extension along a connection axis between a center of the source volume and a center of the collection volume. The source volume has a second cross section source extension along a cross section axis perpendicular to the connection axis. The EUV collector is designed to image the source volume into the collection volume. The imaging has a first imaging scale along the connection axis and a second imaging scale along the cross section axis. The first imaging scale differs from the second imaging scale by at least 10%. The collector has a basic ellipsoidal shape. The difference between the first imaging scale and the second imaging scale results from a shape deviation from such a basic ellipsoidal shape. The collector shape can be described via a Zernike polynomial expansion and the shape deviation comprises contributions of the Zernike polynoms Z4 and/or Z9 and/or Z16.

According to such an aspect, the EUV collector has a basic ellipsoidal shape wherein the difference between the first imaging scale and the second imaging scale results from a shape deviation from such basic ellipsoidal shape. The collector shape of the EUV collector can be described via a Zernike polynomial expansion. The shape deviation between the actual collector shape and the basic ellipsoidal shape comprises contributions of the Zernike polynoms Z4 and/or Z9 and/or Z16. Starting from a basic ellipsoidal shape and implementing the imaging scale difference via a shape deviation from such basic ellipsoidal shape has been proven to be particularly suitable. Analytical concepts derived from the documents mentioned above are well suited for such shape concept.

Optimizing such a shape deviation via Zernike polynomial contributions ZA/Z9/Z16 has been proven to be particularly useful. These Zernike polynoms (Zernike polynomials) are described as fringe Zernike polynomials (SPS ZFR) or as extended fringe Zernike polynomials (ZFE). In that respect, it is referred to the CODE V 10.4 Reference Manual, Appendix C. The fringe Zernike polynomials Z4, Z9 and Z16 are the first fringe Zernike polynomials which only depend on the radius but are independent from the azimuth angle. The fringe Zernike polynomial Z4 corresponds to defocus-field curvature. The fringe Zernike polynomial Z9 corresponds to a primary contribution of the spherical aberration. The fringe Zernike polynomial Z16 corresponds to a secondary contribution to the spherical aberration.

In an aspect, the disclosure provides EUV collector for an EUV projection exposure apparatus to transfer usable EUV light emerging from a source volume into a collection volume which is separated from the source volume. The source volume has a first source extension along a connection axis between a center of the source volume and a center of the collection volume. The source volume has a second cross section source extension along a cross section axis perpendicular to the connection axis. The EUV collector is designed to image the source volume into the collection volume. The imaging has a first imaging scale along the connection axis and a second imaging scale along the cross section axis. The first imaging scale differs from the second imaging scale by at least 10%. The first imaging scale is smaller than the second imaging scale resulting in a collection volume aspect ratio of the collection volume being a ratio of its extension along the connection axis and its extension along the cross section axis, which is smaller than a source volume aspect ratio of the source volume being a ratio of its extension along the connection axis and its extension along the cross section axis.

Such a collection volume aspect ratio that is smaller than a source volume aspect ratio is well adapted to a source volume shape which is larger along the connection axis and accordingly is smaller along the cross section axis. For example, the source volume may have a cigar or ellipsoid type shape extended along the connection axis.

It has been found according to the disclosure that a reason for a limitation of a throughput of usable EUV light is that the source volume of a light source emitting the usable EUV light collected by the EUV collector often significantly deviates from a sphere. Having a collector with different imaging scales along and across a connection axis enables a collection from such aspheric or anisotropically shaped source volume into a collection volume which is better adapted to a subsequent optics of the EUV projection exposure apparatus as in the case of such imaging scales having no difference.

The EUV collector may have an anisotropic imaging characteristic which compensates the anisotropic shape of the source volume.

The design of such a collector with different imaging scales can be done by the help of analytical approaches which, as an example, are described in the paper “Focusing of an elliptical mirror based system with aberrations”,

J. Liu et al., J. Opt. 15 (2013) 105709 (7pp) (doi: 10.1088/2040-8978/15/10/105709) and in the publication “Elliptical mirrors—Applications in microscopy, ed. J. Liu, chapter 6: Aberration analysis of an elliptical mirror with a high numerical aperture”, C. Liu et al., IOP Publishing Ltd 2018 (doi: 10.1088/978-0-7503-1629-3ch6).

An extension of the source volume along the connection axis may be in the range between 400 μm and 2 mm, e.g. in the range between 500 μm and 2 mm or in the range between 400 μm and 1.5 mm. A cross section source extension may be in the range between 100 μm and 1 mm, such as in the range between 500 μm to 1 mm. Boundaries of the respective source extension and/or cross section source extension may be given by a measured 100% enclosed energy volume or by a measured extent of the EUV emitting volume.

The first imaging scale can differ from the second imaging scale by more than 10%. Such an imaging scale difference has been proven to be well adapted to typical plasma source volume shapes. The difference between the first imaging scale and the second imaging scale may be more than 20%, more than 25%, more than 50%, more than 100%, more than 150%, more than 200%, more than 250% and may be more than 300%. As a rule, such imaging scale difference is less than 1,000%.

A reflection surface of the collector can be rotationally symmetric with respect to the connection axis. Such a reflection surface shape can reduce production costs.

A reflection surface of the collector can be a free form surface without an axis of rotational symmetry. Such a reflection surface shape is adaptable to irregular source volume shapes.

Features of a related illumination system and a related projection exposure apparatus correspond to those already described above in relation to the collector of the disclosure.

Features of a related production method and of a nano- or microstructured component produced thereby correspond to those already described above. Such a component may be a semiconductor microchip, such as a high density storage chip.

### BRIEF DESCRIPTION OF THE DRAWINGS

Exemplary embodiments of the disclosure are explained in greater detail below with reference to the drawings, in which:

FIG. 1 schematically shows a projection exposure apparatus for EUV microlithography;

FIG. 2 shows, in a meridional section, a light path to and from a plasma source region of an EUV light source of the projection exposure apparatus according to FIG. 1, wherein an EUV collector is used to transfer usable EUV radiation emerging from the source volume into a separate collection volume;

FIG. 3 again in a meridional section, a light path according to that of FIG. 2 being depicted in a more schematic fashion to show relevant dimensions;

FIG. 4 a schematic side view of a source volume of the light source of FIG. 2, approximated as a cuboid; and

FIG. 5 a schematic side view of a collection volume of the light source of FIG. 2, approximated as a cube.

### DETAILED DESCRIPTION

A projection exposure apparatus 1 for microlithography comprises a light source 2 for illumination light and/or imaging light 3, which will be explained in yet more detail below. The light source 2 is an EUV light source, which produces light in a wavelength range of e.g. between 5 nm and 30 nm, such as between 5 nm and 15 nm. The illumination light and/or imaging light 3 is also referred to as used EUV light below.

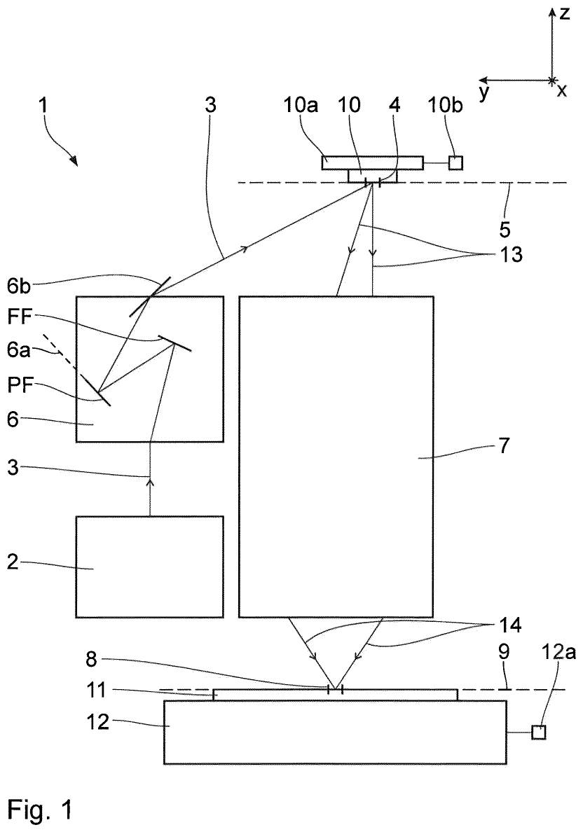

The light source 2 may be a light source with a used EUV wavelength of 13.5 nm or a light source with a used EUV wavelength of 6.9 nm or 7 nm. Other used EUV wavelengths are also possible. A beam path of the illumination light 3 is depicted very schematically in FIG. 1.

An illumination optical unit 6 serves to guide the illumination light 3 from the light source 2 to an object field 4 in an object plane 5. The illumination optical unit comprises a field facet mirror FF depicted very schematically in FIG. 1 and a pupil facet mirror PF disposed downstream in the beam path of the illumination light 3 and likewise depicted very schematically. A field-forming mirror 6b for grazing incidence (GI mirror; grazing incidence mirror) is arranged in the beam path of the illumination light 3 between the pupil facet mirror PF, which is arranged in a pupil plane 6a of the illumination optical unit, and the object field 4. Such a GI mirror 6b is not mandatory.

Pupil facets (not depicted in any more detail) of the pupil facet mirror PF are part of a transfer optical unit, which transfer, and for example image, field facets (likewise not depicted) of the field facet mirror FF into the object field 4 in a manner superposed on one another. An embodiment known from the prior art may be used for the field facet mirror FF on the one hand and the pupil facet mirror PF on the other hand. By way of example, such an illumination optical unit is known from DE 10 2009 045 096 A1.

Using a projection optical unit or imaging optical unit 7, the object field 4 is imaged into an image field 8 in an image plane 9 with a predetermined reduction scale. Projection optical units which may be used to this end are known from e.g. DE 10 2012 202 675 A1.

In order to facilitate the description of the projection exposure apparatus 1 and the various embodiments of the projection optical unit 7, a Cartesian xyz-coordinate system is indicated in the drawing, from which system the respective positional relationship of the components illustrated in the figures is evident. In FIG. 1, the x-direction runs perpendicular to the plane of the drawing into the latter. The y-direction extends to the left in FIG. 1 and the z-direction extends upward in FIG. 1. The object plane 5 extends parallel to the xy-plane.

The object field 4 and the image field 8 are rectangular. Alternatively, it is also possible for the object field 4 and the image field 8 to have a bent or curved embodiment, that is to say a partial ring shape. The object field 4 and the image field 8 have an x/y-aspect ratio of greater than 1. Therefore, the object field 4 has a longer object field dimension in the x-direction and a shorter object field dimension in the y-direction. These object field dimensions extend along the field coordinates x and y.

One of the exemplary embodiments known from the prior art may be used for the projection optical unit 7. What is imaged in this case as an object is a portion of a reflection mask 10, also referred to as reticle, coinciding with the object field 4. The reticle 10 is carried by a reticle holder 10a. The reticle holder 10a is displaced by a reticle displacement drive 10b.

The imaging by way of the projection optical unit 7 is implemented on the surface of a substrate 11 in the form of a wafer, which is carried by a substrate holder 12. The substrate holder 12 is displaced by a wafer or substrate displacement drive 12a.

FIG. 1 schematically illustrates, between the reticle 10 and the projection optical unit 7, a ray beam 13 of the illumination light 3 that enters into the projection optical unit and, between the projection optical unit 7 and the substrate 11, a ray beam 14 of the illumination light 3 that emerges from the projection optical unit 7. An image field-side numerical aperture (NA) of the projection optical unit 7 is not reproduced to scale in FIG. 1.

The projection exposure apparatus 1 is of the scanner type. Both the reticle 10 and the substrate 11 are scanned in the y-direction during the operation of the projection exposure apparatus 1. A stepper type of the projection exposure apparatus 1, in which a stepwise displacement of the reticle 10 and of the substrate 11 in the y-direction is effected between individual exposures of the substrate 11, is also possible. These displacements are effected synchronously to one another by an appropriate actuation of the displacement drives 10b and 12a.

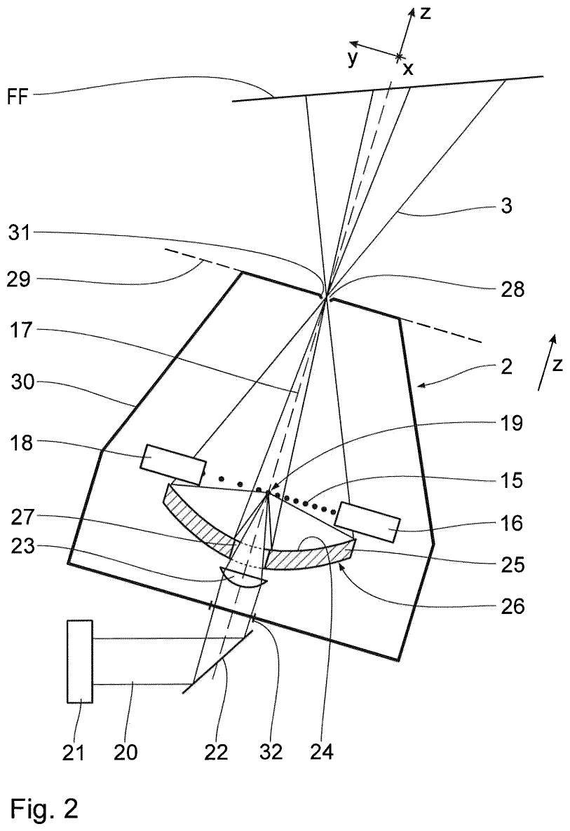

FIG. 2 shows details of the light source 3. Components and functions which correspond to those which were described above with reference to FIG. 1 show the same reference numerals and no more are discussed in detail.

The light source 3 is of the laser produced plasma (LPP) source type. To produce a plasma, tin droplets 15 are generated as a continuous droplet sequence via a tin droplet generator 16. A trajectory of the tin droplets 15 extends across a chief ray direction 17 of the usable illumination light 3. The tin droplets 15 fly freely between the tin droplet generator 16 and a tin droplet receiver 18 while passing a plasma source volume 19. The usable EUV illumination light 3 is emitted from the plasma source volume 19.

Within the source volume 19, the arriving tin droplet 15 is impinged upon with pump light 20 of a pump light source 21. The pump light source 21 may be an infrared laser source, for example a CO₂ laser. The pump light source 21 may be another laser source, such as another infrared laser source, for example a solid state laser, for example a Nd:YAG-laser.

The pump light 20 is transferred into the source volume 19 via a mirror 22 and a focusing lens 23. The mirror 22 may be a controlled tiltable mirror. Control signals to control such mirror 22 may be generated dependent on a respective sensor signal of a sensor monitoring light source parameters and for example, parameters of the pump light source 21.

Due to the pump light impingement, plasma is generated from the tin droplet 15 arriving into the source volume 19. Such generated plasma emits the usable illumination light 3 from the source volume 19. A beam path of the usable illumination light 3 is shown in FIG. 2 between the source volume 19 and the field facet mirror FF which according to his position and arrangement only schematically is shown in FIG. 2. Such illumination light beam path or light path is shown as far as the illumination light 3 is reflected from a reflection surface 24 of a collector mirror 25 of an EUV collector 26.

The collector mirror 25 has a central through-opening 27 for passage of the pump light 20 which is focused via the focusing lens 23 to the source volume 19.

The EUV collector 26 serves to transfer the usable EUV light 3 from the source volume 19 into a collection volume 28 which is embodied as an intermediate focus of the EUV light 3. The collection volume 28 is separated from the source volume 19 along a connection axis between a center of the source volume 19 and a center of the collection volume 28. Such connection axis coincides with the chief ray direction 17 and runs along the z-axis in FIG. 2.

The collection volume 28 is located in an intermediate focus plane 29 of the illumination optical unit 6.

The reflection surface 24 of the collector mirror 25 may carry a grating structure to suppress in the following beam path of the illumination light 3 unwanted erroneous light having wavelengths which differ from an EUV wavelength of the illumination light 3 used to illuminate the reticle 10. Such erroneous light wavelengths may be in the IR and/or in the DUV wavelength range.

The field facet mirror FF is arranged in a far-field of the illumination light 3 in the beam path after the collection volume 28.

The EUV collector 26 and further components of the light source 2, for example the tin droplet generator 16, the tin droplet receiver 18 and the focusing lamps 23 are located within a vacuum chamber 30. Surrounding the collection volume 28, the vacuum chamber 30 has a through-opening 31. Located at an entrance of the pump light 20 into the vacuum chamber 30, the latter has a pump light entry window 32.

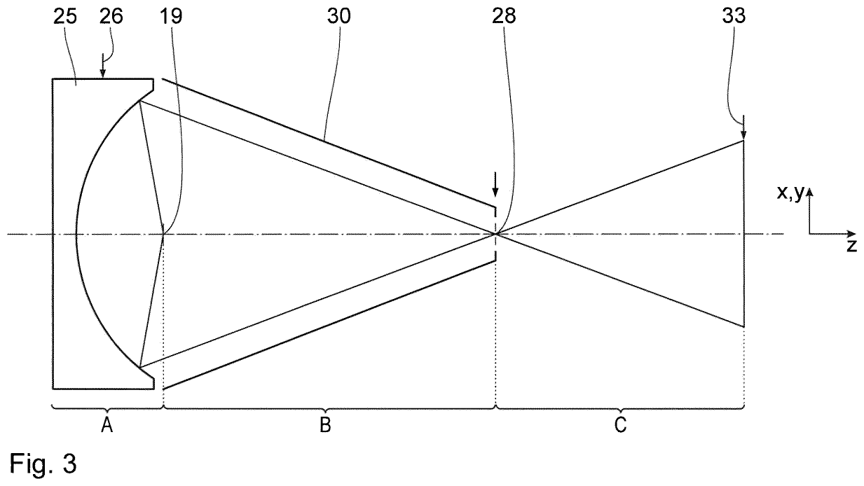

FIGS. 3 to 5 show typical dimensions, which are important with respect to imaging properties of the collector mirror 25 of the EUV collector 26. As the dimensions discussed in that respect have rotational symmetry with respect to the z-axis, no difference is made with respect to coordinates x and y which both run vertical in FIGS. 3 to 5. The z-axis in FIGS. 3 to 5 runs horizontal. To represent a far-field, in FIG. 3 a far-field plane 33 is depicted.

A distance A between a backside of a substrate of the collector mirror 25 and the center of the source volume 19 may be in the range between 150 mm and 300 mm.

A distance B between the center of the source volume 19 and the center of the collection volume 28 may be larger than 1 m and may be in the range between 1 m and 1.5 m.

A distance C between the center of the collection volume 28 and the far-field plane 33 may be larger than 500 mm and may be in the range between 500 mm and 1,500 mm.

Due to the tin droplet/pump light interaction, the source volume 19 has a first source extension zₛ along the connection axis z between the center of the source volume 19 and the center of the collection volume 28. Such z source extension zₛ may be in the range between 200 μm and 1.5 mm and may be in the range between 300 μm and 1 mm.

Further, the source volume 19 has a second, cross section source extension xₛ, yₛ along its cross section axes x and y perpendicular to the connection axis z. Such cross section source extension xₛ, yₛ may be in the range between 100 μm and 1 mm, such as in the range between 200 μm and 600 μm, e.g. around 500 μm.

A ratio zₛ/xₛ (=zₛ/yₛ) may be in the range between 1.5 and 5, such as in the range between 2 and 4, e.g. in the range of 3.

The collection volume 28 has a first collection volume extension z_{c} along the connection axis z and a second, cross section collection extension x_{c}, y_{c} along the cross section axes x and y.
x_{c} (=y_{c} and z_{c}) may be in the range between 1 mm and 5 mm.

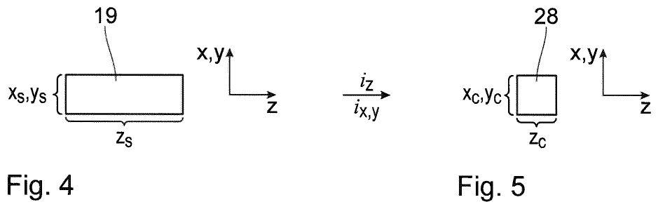

The EUV collector mirror 25 is designed to transfer the source volume 19 into the collection volume 28 with different imaging scales with respect to the z-axis on the one hand and with respect to the x- and y-axes on the other. Such imaging via the collector mirror 25 is with a first imaging scale i_{z} (i_{z}=z_{c}/zₛ) along the connection axis z and with a second, cross section imaging scale iₓ (=i_{y}=x_{c}/xₛ=y_{c}/yₛ) along the cross section axes x and y. The first imaging scale i_{z} differs from the second imaging scale iₓ, i_{y} by at least 10%. For example, a ratio between the first imaging scale i_{z} and the second imaging scale iₓ, i_{y} is in the range of 1.5 to 5, such as in the range of 2 to 4, e.g. in the range of 3. For example and as shown in FIGS. 4 and 5, such imaging scale ratio i_{z}/iₓ, y is complementary to the ratio zₛ/xₛ, yₛ resulting in a compensation of the extension anisotropy of the source volume 19 via the collector imaging into the collection volume 28.

In the schematic depiction of FIGS. 4 and 5, the source volume is shown as a cuboid having a rectangular cross section and the collection volume is shown as a cube having a quadratic cross section. In practice, the volumes 19 and 28 have no edged shape but have more smooth outshape which with respect to the source volume may resemble an ellipsoid or a deformed ellipsoid and in case of the collection volume may resemble a sphere or a deformed sphere.

The imaging properties of the collector mirror 25 can be such that a z/x, z/y collection volume aspect ratio is smaller than a z/x, z/y source volume aspect ratio. In the exemplified embodiment of FIGS. 4 and 5, the z/x collection volume aspect ratio is 1 and the z/x source volume aspect ratio is 3.

The reflection surface 24 of the collector mirror 25 has a basic ellipsoidal shape having a first focal point located within the source volume 19 and a second focal point located within the collection volume 28.

A difference between the first imaging scale i_{z} and the second imaging scales iₓ, i_{y} results from a shape deviation of the reflection surface 24 from such basic ellipsoidal shape.

The shape of the reflection surface 24 of the collector mirror 25 can be described via a Zernike polynomial expansion. The shape deviation of the reflection surface 24 from a basic shape, such as from a basic ellipsoidal shape, represents contributions of the Zernike polynoms Z4 and/or Z9 and/or Z16.

The reflection surface 24 of the collector mirror 25 is rotational symmetric with respect to the connection axis z.

In an alternative embodiment, the reflection surface 24 of the collector mirror 25 is embodied as a free form surface without an axis of rotational symmetry.

The respective adaption of the imaging scales i_{z} on the one hand and i_{x,y} on the other results in a reduction of unwanted clipping of usable EUV light 3 at an aperture located in the vicinity of the collection volume 28, i.e., located at the through-opening 31. Such aperture serves to hold back unwanted extraneous light, pump light and/or debris.

In order to produce a microstructured or nanostructured component, the projection exposure apparatus 1 is used as follows: First, the reflection mask 10 or the reticle and the substrate or the wafer 11 are provided. Subsequently, a structure on the reticle 10 is projected onto a light-sensitive layer of the wafer 11 with the aid of the projection exposure apparatus 1. Then, a microstructure or nanostructure on the wafer 11, and hence the microstructured component, is produced by developing the light-sensitive layer.

What is claimed is:

1. An EUV collector configured to transfer usable EUV light emerging from a source volume into a collection volume which is separated from the source volume, wherein:
the source volume has a first extension along a connection axis between a center of the source volume and a center of the collection volume;
the source volume has a second extension along a cross section axis perpendicular to the connection axis;
the EUV collector is configured to image the source volume into the collection volume so that the imaging has a first imaging scale along the connection axis and a second imaging scale along the cross section axis;
the first imaging scale differs from the second imaging scale by at least 10%;
the collector has a basic ellipsoidal shape;
the difference between the first imaging scale and the second imaging scale is due to a shape deviation from the basic ellipsoidal shape;
the collector shape is describable via a Zernike polynomial expansion; and
the shape deviation comprises contributions of the Zernike polynoms Z4 and/or Z9 and/or Z16.

2. The EUV collector of claim 1, wherein the first imaging scale differs from the second imaging scale by more than 10%.

3. The EUV collector of claim 1, wherein the first imaging scale differs from the second imaging scale by more than 50%.

4. The EUV collector of claim 1, wherein the first imaging scale differs from the second imaging scale by more than 100%.

5. The EUV collector of claim 1, wherein a reflection surface of the collector is rotationally symmetric with respect to the connection axis.

6. The EUV collector of claim 1, wherein a reflection surface of the collector is a free form surface without an axis of rotational symmetry.

7. An EUV illumination system, comprising:
a radiation source comprising a collector according to claim 1; and
mirrors.

8. An EUV projection exposure apparatus, comprising:
an illumination system, comprising:
a radiation source comprising a collector according to claim 1; and
mirrors; and
a projection objective configured to image an object field illuminated by the EUV illumination system into an image field in an image plane.

9. A method of using a projection exposure apparatus comprising an illumination system and a projection objective, the method comprising:
using the illumination system to illuminate an object in an object field of an object plane; and
using the projection objective to image the illuminated object field into an image field in an image plane,
wherein the illumination system comprises a radiation source comprises a collector according to claim 1.

10. An EUV collector configured to transfer usable EUV light emerging from a source volume into a collection volume which is separated from the source volume, wherein:
the source volume has a first extension along a connection axis between a center of the source volume and a center of the collection volume;
the source volume has a second extension along a cross section axis perpendicular to the connection axis;
the EUV collector is configured to image the source volume into the collection volume so that the imaging has a first imaging scale along the connection axis and a second imaging scale along the cross section axis;
the first imaging scale differs from the second imaging scale by at least 10%;
the first imaging scale is smaller than the second imaging scale so that a collection volume aspect ratio of the collection volume is less than a source volume aspect ratio of the source volume;
the collection volume aspect ratio of the collection volume is a ratio of an extension of the collection volume along the connection axis to an extension of the collection volume along the cross section axis; and
the source volume aspect ratio of the source volume is a ratio of an extension of the source volume along the connection axis to an extension of the source volume along the cross section axis.

11. The EUV collector of claim 1, wherein the first imaging scale differs from the second imaging scale by more than 10%.

12. The EUV collector of claim 1, wherein the first imaging scale differs from the second imaging scale by more than 50%.

13. The EUV collector of claim 1, wherein the first imaging scale differs from the second imaging scale by more than 100%.

14. The EUV collector of claim 1, wherein a reflection surface of the collector is rotationally symmetric with respect to the connection axis.

15. The EUV collector of claim 11, wherein a reflection surface of the collector is a free form surface without an axis of rotational symmetry.

16. The EUV collector of claim 11, wherein:
the collector has a basic ellipsoidal shape;
the difference between the first imaging scale and the second imaging scale is due to a shape deviation from the basic ellipsoidal shape;
the collector shape is describable via a Zernike polynomial expansion; and
the shape deviation comprises contributions of the Zernike polynoms Z4 and/or Z9 and/or Z16.

17. The EUV collector of claim 16, wherein the first imaging scale differs from the second imaging scale by more than 10%.

18. An EUV illumination system, comprising:
a radiation source comprising a collector according to claim 11; and
mirrors.

19. An EUV projection exposure apparatus, comprising:
an illumination system, comprising:
a radiation source comprising a collector according to claim 11; and
mirrors; and
a projection objective configured to image an object field illuminated by the EUV illumination system into an image field in an image plane.

20. A method of using a projection exposure apparatus comprising an illumination system and a projection objective, the method comprising:
using the illumination system to illuminate an object in an object field; and
using the projection objective to image the illuminated object field into an image field in an image plane,
wherein the illumination system comprises a radiation source comprises a collector according to claim 11.
